(19) United States
(12) Patent Application Publication
(10) Pub. No.: US 2005/0200869 A1
(43) Pub. Date: Sep. 15, 2005

(54) Image data color conversion device

(76) Inventor: Ikuo Hayaishi, Nagano-ken (JP)

Correspondence Address: MARTINE PENILLA & GENCARELLA, LLP, 710 LAKEWAY DRIVE, SUITE 200, SUNNYVALE, CA, 94085, US

(21) Appl. No.: 11/070,777

(22) Filed: Mar. 1, 2005

(30) Foreign Application Priority Data
Mar. 2, 2004 (JP) 2004-57733

(51) Int. Cl. G06F 15/00; G03F 3/08

(52) U.S. Cl. 358/1.9; 358/518

(57) ABSTRACT

When the CPU 411 detects image process control data in the acqureed image file, a color conversion process is executed on the image data using the image process control data. When the CPU 411 cannot detect the image process control data, CPU 411 determines if the image file includes an ICC profile. When an ICC profile is detected, a color conversion process is executed on the image data using the ICC profile. When the CPU 411 cannot detect the image process control data or ICC profile, CPU 411 determines if the image file includes shooting information. When shooting information is detected, a color conversion process is executed on the image data using the shooting information.

### BACKGROUND OF THE INVENTION

1. Field of the Invention

The invention relates to an image processing technique for implementing a color conversion process on image data using color conversion data defining the color conversion conditions for the image data.

2. Description of the Related Art

ICC profiles are widely known as color conversion data used in color conversion processes on image data. ICC profiles are color conversion profiles having a format defined by the International Color Consortium. ICC profiles are data for carrying out a color conversion process between the machine-dependent color space of the device handling the image data and machine-independent color space, and are recorded, for example, in the form of a table, matrix, or the like.

The present Applicant has realized a technique capable of image processing that reflects the photographer's intention by associating image data with image process control data (commands or parameters) indicating the image processing conditions in an image processing device. The image process control data includes color conversion data in which the combination of the image data-producing device and image output device has been taken into account.

In another technique that has been realized for image data produced by a DSC, the image data produced by a DSC and the shooting information (shooting conditions) from when the image data was produced are stored in the same file, and images are processed by the image processing device using the shooting data. The image files used in this technique conform to the specifications of the Exif file format established by the Japan Electronics and Information Technology Industries Association (JEITA). Data on the color space from when the image data was produced is recorded in the shooting information.

The use of any of the three above types of color conversion data allows a color conversion process adapted to the image data to be performed. However, the above three types of color conversion data have not conventionally been used as mutually supplementing data. As such, in image processing devices making use of a specific type of color conversion data among the above three types, it has not been possible to perform a color conversion process adapted to the image data when the specific color conversion data could not be used.

### SUMMARY OF THE INVENTION

To address the above problems, an object of the present invention is to realize a color conversion process adapted to image data by making effective use of color conversion data associated with the image data.

A first aspect of the invention for addressing the above object provides an image processing device for implementing a color conversion process on image data that is associated with at least one of first through third color conversion data. The image processing device in the first aspect of the invention comprises a image data acquiring module that acquires the image data; color conversion data retrieval module that retrieves the first through third color conversion data associated with the acquired image data; and color conversion processing module that executes the color conversion process on the image data according to the first color conversion data when the first color conversion data is retrieved.

According to the image processing device in the first aspect of the invention, the first through third color conversion data associated with the acquired image data are retrieved, and the color conversion process is executed on the image data according to the first color conversion data when the first color conversion data is retrieved, thereby allowing a color conversion process adapted to the image data to be carried out by making effective use of color conversion data associated with the image data.

In the image processing device in the first aspect of the invention, the color conversion processing module executes the color conversion process on the image data according to the second color conversion data when the first color conversion data is not retrieved but the second color conversion data is retrieved. This arrangement allows a color conversion process to be executed on the image data using the second color conversion data when the first color conversion data is not retrieved. A color conversion process adapted to the image data may thus be carried out by making effective use of color conversion data associated with the image data.

In the image processing device in the first aspect of the invention, the color conversion processing module executes the color conversion process on the image data according to the third color conversion data when the second color conversion data is not be retrieved but the third color conversion data is retrieved. This arrangement allows a color conversion process to be executed on the image data using the third color conversion data when the first and second color conversion data are not retrieved. A color conversion process adapted to the image data may thus be carried out by making effective use of color conversion data associated with the image data.

The image processing device in the first aspect of the invention may further comprise storage module that stores default color conversion data, wherein the color conversion processing module executes the color conversion process on the image data according to the default color conversion data when the third color conversion data is not retrieved. This arrangement allows a color conversion process to be executed on the image data even when the color conversion data associated with the image data is not retrieved.

In the image processing device in the first aspect of the invention, the first color conversion data may be image process control data defining the image processing conditions for associated image data, the second color conversion data may be ICC profiles, and the third color conversion data may be shooting information indicating the conditions at the time of the shooting. Because of the image process control data includes the optimal color conversion data for the image data, the color conversion data can be retrieved in that order to improve the accuracy of the color conversion process.

The image processing device in the first aspect of the invention may further comprise output image data generating module that generates output image data using the color converted image data; and image output module that outputs images using the generated output image data. In this case, output images can be obtained using image data that is color converted.

A second aspect of the invention provides an image processing device for executing a color conversion process on image data using image files that store at least any one of image data, image process control data which defines the image processing conditions for the image data and which is storable in a plurality of storage locations in a recording format, ICC profiles in which the storage location in a recording format is defined, and shooting information indicating the conditions at the time the photograph was taken, in which the storage location in a recording format is defined. The image processing device in the second aspect of the invention comprises: image file acquiring module that acquires the image files; format determination module that determining the recording format of the acquired image file; image process control data retrieval module that retrieves image process control data at the plurality of storage locations according to the determined recording format; and color conversion processing module that executes the color conversion process on the image data according to the retrieved image process control data when the image process control data is retrieved.

According to the image processing device in the second aspect of the invention, image process control data may be retrieved at a plurality of storage locations according to the determined recording format, and the color conversion process may be executed on the image data according to the retrieved image process control data when the image process control data is retrieved. A color conversion process adapted to the image data can thus be carried out by making effective use of color conversion data associated with the image data.

The image processing device of the second aspect of the invention may further comprise ICC profile retrieval module that retrieves ICC profiles at the defined storage location when the image process control data is not retrieved at the at the plurality of storage locations, wherein the color conversion processing module executes the color conversion process on the image data according to the ICC profile when the ICC profile is retrieved. This arrangement allows a color conversion process to be executed on the image data using the ICC profile even when image process control data is not retrieved, thereby allowing a color conversion process adapted to the image data to be carried out by making effective use of color conversion data associated with the image data.

The image processing device of the second aspect of the invention may further comprise shooting information retrieval module that retrieves shooting information at the defined storage location when the ICC profile is not retrieved at the defined storage location, wherein the color conversion processing module executes the color conversion process on the image data according to the shooting information when the shooting information is retrieved. This arrangement allows a color conversion process to be executed on the image data using the shooting information even when image process control data or the ICC profile is not retrieved, thereby allowing a color conversion process adapted to the image data to be carried out by making effective use of color conversion data associated with the image data.

In the image processing device of the second aspect of the invention, the image file may be a JPEG data storage file having at least any one of a first application marker segment in which the image process control data is storable, a second application marker segment in which the ICC profile is storable, and a third application marker segment in which at least one of the image process control data or shooting information is storable at the same hierarchy, and the image process control data retrieval module may retrieve the image process control data in the order of the storage location of the third application marker segment and the storage location of the first application marker segment. This arrangement allows all of the image process control data to be retrieved.

In the image processing device of the second aspect of the invention, the image file may be a JPEG data storage file having at least any one of a first application marker segment in which the image process control data is storable, a second application marker segment in which the ICC profile is storable, and a third application marker segment in which at least one of the image process control data or shooting information is storable at the same hierarchy, and the image process control data retrieval module retrieves the image process control data in the order of the storage location of the first application marker segment and the storage location of the third application marker segment. This arrangement allows all of the image process control data to be retrieved.

The image processing device of the second aspect of the invention may further comprise shooting information retrieval module that retrieves the shooting information from the third application marker segment, wherein the third application marker segment is capable of storing the image process control data at a subordinate hierarchy of the shooting information, and the image process control data retrieval module retrieves the image process control data at a subordinate hierarchy of the shooting information of the third application marker segment when image process control data is not retrieved at the storage locations of the first and third application marker segments but the shooting information is retrieved by the shooting information retrieval module. This arrangement allows all of the image process control data to be retrieved.

The image processing device of the second aspect of the invention may further comprise ICC profile retrieval module that retrieves the ICC profile from the second application marker segment, wherein the color conversion processing module executes the color conversion process on the image data using the retrieved ICC profile when the image process control data is not retrieved by the image process control data retrieval module but the ICC profile is retrieved by the ICC profile retrieval module. This arrangement allows the color conversion process to be executed on the image data using the ICC profile when the image process control data cannot be retrieved.

In the image processing device of the second aspect of the invention, the color conversion processing module executes a color conversion process on the image data using the shooting information when the ICC profile is not retrieved from the second application marker segment but the shooting information is retrieved from the third application marker segment. This arrangement allows the color conversion process to be executed on the image data using the shooting information when the image process control data and ICC profile cannot be retrieved.

In the image processing device of the second aspect of the invention, the image file may be a TIFF file having at least any one of a first in image file directory in which the image process control data is storable, a second image file directory in which the ICC profile is storable, and a third image file directory in which the shooting information is storable, and the image process control data retrieval module may retrieve the image process control data in the order of the storage location of the first image file directory and the third image file directory. This arrangement allows all of the image process control data to be retrieved.

The image processing device of the second aspect of the invention may further comprise shooting information retrieval module that retrieves the shooting information from the third image file directory, wherein the third image file directory is capable of storing the image process control data at a subordinate hierarchy of the shooting information, and the image process control data retrieval module retrieves the image process control data at a subordinate hierarchy of the shooting information of the third image file directory when image process control data is not retrieved at the first image file directory but the shooting information is retrieved by the shooting information retrieval module. This arrangement allows all of the image process control data to be retrieved.

The image processing device of the second aspect of the invention may further comprise ICC profile retrieval module that retrieves the ICC profile from the second image file directory, wherein the color conversion processing module executes the color conversion process on the image data using the ICC profile that is retrieved when the image process control data is not retrieved by the image process control data retrieval module but the ICC profile is retrieved by the ICC profile retrieval module. This arrangement allows the color conversion process to be executed on the image data using the ICC profile when the image process control data cannot be retrieved.

In the image processing device of the second aspect of the invention, the color conversion processing module executes a color conversion process on the image data using the shooting information when the ICC profile is not retrieved from the second image file directory but the shooting information is retrieved from the third image file directory. This arrangement allows the color conversion process to be executed on the image data using the shooting information when the image process control data and ICC profile cannot be retrieved.

A third aspect of the invention provides an image processing method of implementing a color conversion process on image data that is associated with at least one of first through third color conversion data. The image processing method of the third aspect of the invention comprises acquiring the image data; retrieving the first through third color conversion data associated with the acquired image data; and executing the color conversion process on the image data according to the first color conversion data when the first color conversion data is retrieved.

The image processing method in the third aspect of the invention affords the same action and effects as the image processing device in the first aspect of the invention. The image processing method in the third aspect of the invention can also be worked in a variety of applications in the same manner as the image processing device in the first aspect of the invention, and can provide the same action and effects in those applications.

A fourth aspect of the invention provides an image processing method of executing a color conversion process on image data using image files that store at least any one of image data, image process control data which defines the image processing conditions for the image data and which is storable in a plurality of storage locations in a recording format, ICC profiles in which the storage location in a recording format is defined, and shooting information indicating the conditions at the time of the shooting, in which the storage location in a recording format is defined. The image processing method of the fourth aspect of the invention comprises acquiring the image files; determining the recording format of the acquired image file; retrieving image process control data at the plurality of storage locations according to the determined recording format; and executing the color conversion process on the image data according to the retrieved image process control data when the image process control data is retrieved.

The image processing method in the fourth aspect of the invention affords the same action and effects as the image processing device in the second aspect of the invention. The image processing method in the fourth aspect of the invention can also be worked in a variety of applications in the same manner as the image processing device in the second aspect of the invention, and can provide the same action and effects in those applications.

The methods in the third and fourth aspects of the invention can also be worked in the form of programs and computer-readable recording media on which such programs are recorded.

### BRIEF DESCRIPTION OF THE DRAWINGS

FIG. 1 illustrates the schematic structure of an image processing system comprising an image processing device in an embodiment of the invention.

FIG. 2 illustrates the schematic structure of an image processing device in an embodiment of the invention.

FIG. 3 is a block diagram of the functional modules realized by the control circuit of a color printer in an embodiment of the invention.

FIG. 4 schematically illustrates the internal structure of a JPEG data storage file at the application marker segment (APP) level in order to describe the file format of the JPEG data storage file in which JPEG data is stored.

FIG. 5 illustrates an example of data stored as image process control data GI.

FIG. 6 illustrates an example of data stored as the ICC profile ICC.

FIG. 7 illustrates an example of data stored as shooting information SI.

FIG. 8 schematically illustrates the internal structure of a TIFF file at the IFD level in order to describe the TIFF file format.

FIG. 9 is a flow chart of the routine of the image process including the color conversion process in the color printer of the embodiment.

FIG. 10 is a flow chart of a process routine for detecting image process control data.

FIG. 11 is a flow chart of a process routine for retrieving ICC profiles.

FIG. 12 is a flow chart of a process routine for detecting shooting information.

### DESCRIPTION OF THE PREFERRED EMBODIMENTS

The image processing device, image processing method, and image processing programs of the invention are illustrated in the following examples with reference to the drawings.

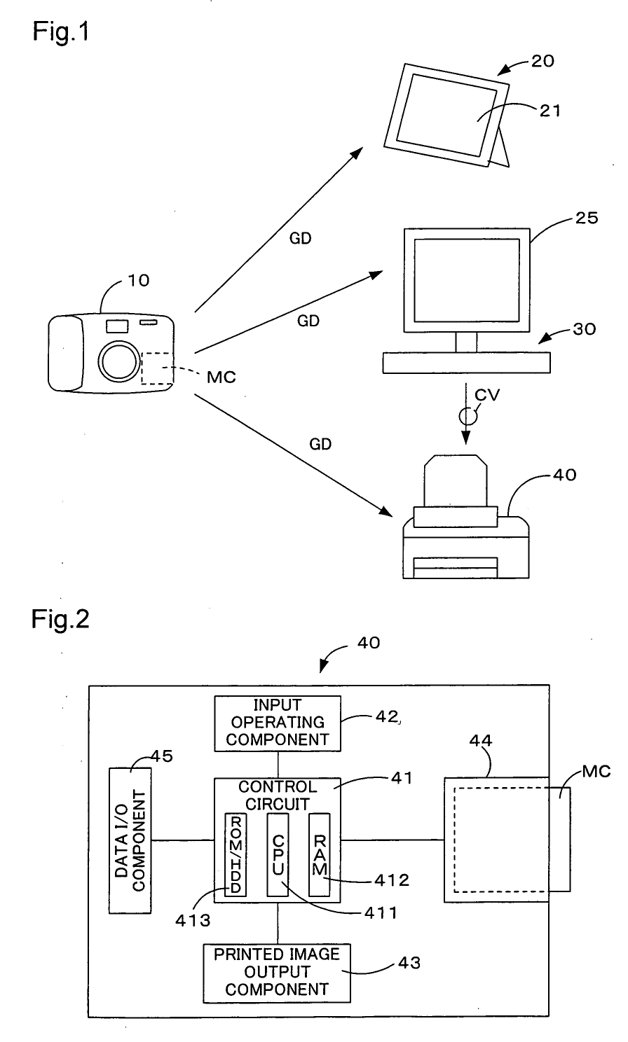

An image processing system comprising the image processing device in this example will be described with reference to FIGS. 1 and 2. FIG. 1 illustrates the schematic structure of the image processing system comprising the image processing device in the embodiment of the invention. FIG. 2 illustrates the schematic structure of the image processing device in the embodiment of the invention.

The image processing system comprises a digital still camera 10 as the image data generating device, a display device 20 as the image processing device for executing the image process on the image data GD, a personal computer or 30, and a color printer 40.

The digital still camera 10 is a camera in which digital image data is obtained (generated) by focusing light data on a digital device (photoelectric transformer elements known as CCD or photoelectric multipliers). The digital still camera 10 comprises a CCD in which, for example, R, G, and B filters for the various constituent pixels are arranged according to certain rules, and generates digital image data corresponding to the photographed subject. More specifically, R color component image data is directly obtained in pixels with R filters, and image data for the G and B color components is generated by interpolation based on the surrounding image data. That image data that is generated is stored on a memory card MC serving as a storage device. Image data storage formats used in digital still cameras 10 are generally the JPEG data format in the form of an irreversible compression storage format and the TIFF data format in the form of a reversible compression storage format, but other storage formats include the RAW data, GIF data, and BMP data formats. Other image data generating devices include photographic devices such as scanners.

The display device 20 has a display 21 for displaying images, functioning as a photoelectric photograph frame, for example, and displays output images by processing image data by the same image processing as the image processing in the stand alone color printer 40 as described below. The display device 20 obtains image data through, for example, recording media, wireless communications such as IR communications or radio wave communications, or through cables from a digital still camera 10 or server on a network (not shown). The display 21 is, for example, a liquid crystal display or organic EL display, and has the property of independent image output on each display panel.

The personal computer 30 is, for example, a general purpose type of computer, comprising a CPU, RAM, and hard disk, and executes image processes similar to the image processes in the color printer 40 as described below. The personal computer 30 also comprises a memory card slot for the installation of a memory card MC, and I/O terminals to connect cables from the digital still camera 10 or the like.

The color printer 40 is capable of outputting color images. In this example, the color printer 40 stands alone and outputs images by running image processes on image data. As illustrated in FIG. 2, the color printer 40 comprises a control circuit 41, I/O operating component 42, printed image output component, memory card slot 44, and data I/O component 45.

The control circuit 41 comprises a central processing unit (CPU) 411 for running various computing processes such as image processing and analytical processes on image data, random access memory (RAM) 412 for temporarily storing various types of data such as image data which has undergone an image process and computer results, and a read-only memory (ROM)/hard disk drive (HDD) for storing tables that show various parameters such as photograph element determination conditions to identify major photograph elements which characterize images and programs that are run by the CPU 111.

The I/O operating component 42 is an interface which receives external input, and can be realized in the form of a key operator, scroll operator, touch panel type operator, or the like.

The printed image output component 43 is an ink jet type of printed image output component that forms images by forming dot patterns by spraying four colors of ink comprising cyan (C), magenta (M), yellow (Y), and black (K) onto print media based on the print image data output from the control circuit 41. Alternatively, it is an electronic copier type of printed image output device that forms images by transferring and fixing color toner on print media. In addition to the four colors noted above, the colored ink may include light cyan (LC), light magenta (LM), blue, and red.

The memory card slot 44 is a component for the installation of various memory cards. Reading and writing to the memory card installed in the memory card slot 44 are controlled by the control circuit 41.

The data I/O component 45 has terminals for connecting cable CV and the like, and a signal transforming process function, and is used for the exchange of image data with external devices.

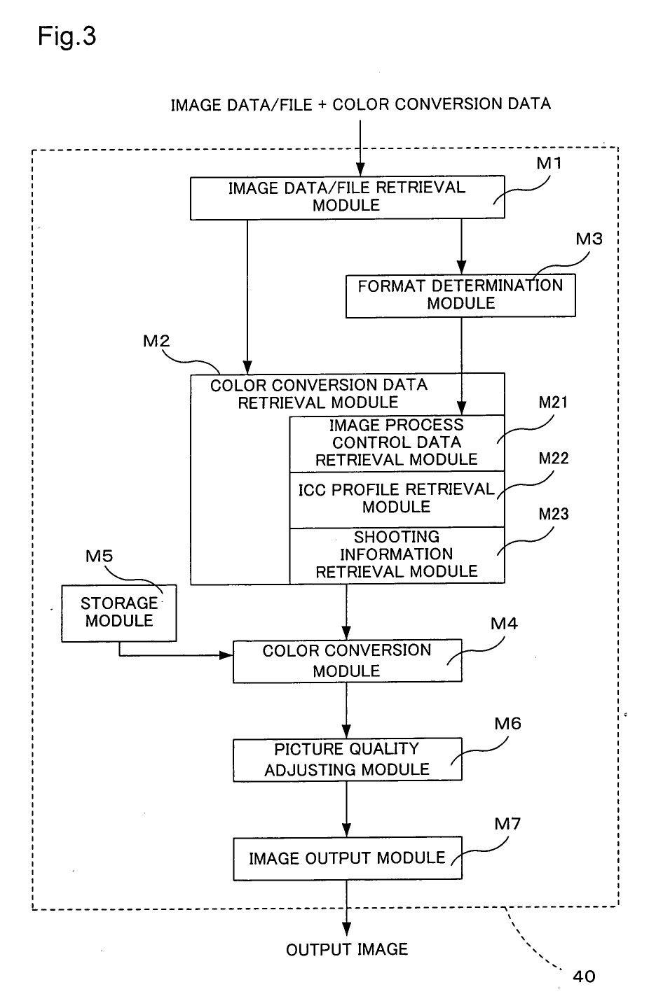

An outline of the modules realized by the control circuit 41 of the color printer 40 is given below with reference to FIG. 3. FIG. 3 is a block diagram of the functional modules realized by the control circuit 41 of the color printer 40 in the embodiment of the invention. The modules illustrated in FIG. 3 can be realized in terms of the CPU 411 alone or the control circuit 41, and can be realized by either hardware or software.

The image file GF comprising the image data GD and the color conversion data is acquired by the control circuit 41 by means of the image data/file acquisition module M1, and is sent to the color conversion data retrieval module M2.

The color conversion data retrieval module M2 retrieves color conversion data contained in the image file GF or associated with the image data GD.

Alternatively, the image data/image file acquisition module M1 sends the acquired image file GF to the format determination module 3. The format determination module M3 determines where the format of the image file GF is, for example, JPEG format or TIFF format. That is because the storage location of the color conversion data depends on the format of the image file GF. The color conversion data retrieval module M2 is realized by an image process control data retrieval module M21, ICC profile retrieval module M22, and shooting information retrieval module M23. These retrieval modules M21, M22, and M23 retrieve the image file according to the determined format. For example, the image process control data retrieval module M21 first retrieves the image process control data GI. When the image process control data GI cannot be retrieved, the ICC profile retrieval module M22 retrieves the ICC profile. When the ICC profile cannot be retrieved, the shooting information retrieval module M23 retrieves the shooting information SI.

A color conversion module M4 executes a color conversion process on the image data using the color conversion data that has been retrieved. When the color conversion module M4 cannot retrieve the color conversion data from the image file GF, the color conversion process is performed on the image data GD using default color conversion data stored in a storage module M5.

A picture quality adjusting module M6 performs a picture quality adjustment process on the image data GD which has undergone color conversion. An image output module M7 outputs the output image using the image data which has undergone the picture quality adjustment process.

Structure of Image File

The image file GF in this example can comprise, for example, a file structure according to the Exif format (Exif file) proposed by the Japan Electronics and Information Technology Industries Association (JEITA) as specifications for a digital still camera image file format; a file format according to the JFIF format (JFIF file), a specification aimed at JPEG data file compatibility, established by the three companies C-Cube Microsystems, Xing Technology, and Digital Origin (Radius); and a file structure according to the TIFF format (TIFF file) in which image data-related parameters are specified in tag format. Exif files can be classified into JPEG-Exif files storing irreversible compression type JPEG image data and TIFF-Exif files storing reversible compression type TIFF image data.

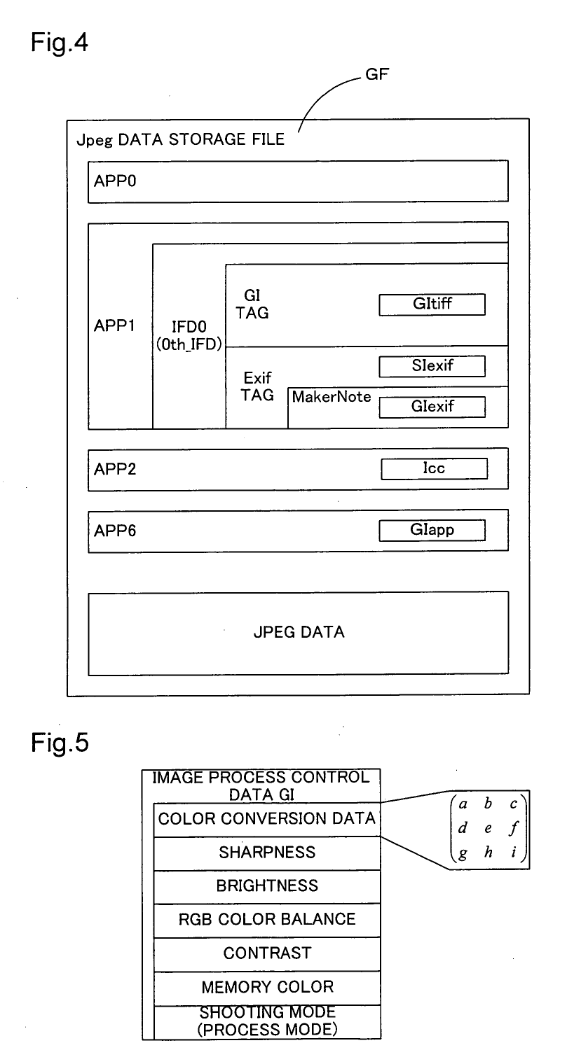

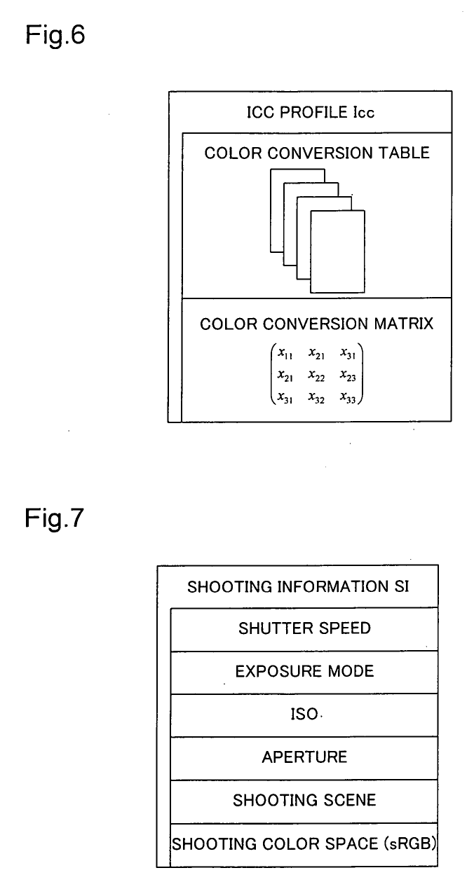

The general structure of image files according to JPEG data storage file formats which can be used in the example will be described with reference to FIGS. 4 to 7. FIG. 4 schematically illustrates the internal structure of a JPEG data storage file at the application marker segment (APP) level in order to describe the file format of the JPEG data storage file in which JPEG data is stored. FIG. 5 illustrates an example of data stored as image process control data GI. FIG. 6 illustrates an example of data stored as the ICC profile Icc. FIG. 7 illustrates an example of data stored as shooting information SI. In this example, the terms file structure, data structure, and storage area mean file or data images in a form in which the files or data, etc., are stored in a recording device.

The basic file format of the JPEG data storage file is described with reference to FIG. 4. As noted above, JFIF files and Exif files are generally used as JPEG data storage files. From the stand point of file format, JPEG data storage files are files comprising application marker segments and JPEG data. A JPEG data storage file is based on the JFIF format when the JPEG data storage file has APP0, which is a 0 place application marker segment, and is based on the Exif format when the JPEG data storage file has only APP1, which is an application marker segment in the first place, or APP1 and APP2, which are application marker segments in the first and second places. Image process control data GI including data related to the color conversion data is stored in IFD (image file directory) units are stored in the application marker segments APPn, as illustrated by application marker segment APP1. The IFDs in application marker segments APP2 and APP6 are not illustrated.

The image process control data GI is stored in the form of GI app data in the application marker segment APP6. The image process control data GI can also be stored in the form of GI tiff data in the GI tag and GI exif data in the Exif tag included in the APP1. The different additional characters app, tiff, and exif have been added to the GI tags for the sake of convenience to readily indicate the different storage positions, but the contents of the data are all the same. The file structures of the file formats are described in detail below.

JPEG data storage files (image files GF) are composed of a plurality of marker segments and JPEG image data GD. The plurality of marker segments include SOI marker segment indicating the head of the segment compression data; the application marker segments APPn (n=number of characters) which are the marker segments storing the data defined by the file format; DQT marker segment defining quantization tables; DHT marker segment defining Huffman tables; DRI marker segment defining restart interpolation intervals; SOF marker segment showing the types of frame-related parameters; SOS marker segment showing the types of scanning-related parameters; and EOI marker segment showing the end of the compression data. The compression image data GD is stored between SOS and EOI marker segments. The marker segments may be recorded in any order except that the APPn marker segments are recorded immediately after the SOI marker segment, and the SOS marker segment is recorded with the image data GD between immediately before the EOI marker segment.

The image process control data GI includes identification character data to indicating that the data is image process control data GI, data on the version of image process control data GI, and various types of data including the various types of parameters related to picture quality adjustment of the image data. The image process control data GI includes data related to picture quality adjustment such as color conversion data, sharpness, brightness, RGB color balance, contrast, memory colors, and photographic mode, as shown in FIG. 5. Specifically, the data (parameters) are indicated by offset values from standard locations, and the indicated values (settings) of the parameters are noted in the indicated locations. For example, data indicating the color space used during the image process in the color printer 40 and personal computer 30, that is, data for conversion to the designated color space (such as 3×3 color space matrix values), are noted as the color conversion data.

The ICC profile Icc is stored in the application marker segment APP2. The ICC profile Icc is data for color conversion prepared for each device that produces image data. Data by which image data produced in the machine-dependent color space of the image data generating devices is converted to machine-independent color space that does not depend on the image data generating device is recorded in the ICC profile Icc. It is recorded, for example, in the form of color conversion tables and color conversion matrices, as illustrated in FIG. 6. Although not illustrated in FIG. 4, the ICC profile Icc stores the Icc data in IFD units.

The shooting information SI is stored in the application marker segment APP 1. Well known Exif data, for example corresponds to image data SI. The shooting information SI is data related to the picture quality at the time the image data is produced (the time the photograph is taken) in a image data generating device such as the digital still camera 10. As illustrated in FIG. 7, for example, the shutter speed, exposure mode, ISO sensitivity, aperture, shooting scene, and shooting color space are include. The shooting color space means the color space used to produce image data in the digital still camera 10, that is, the color space of the image data produced by the digital still camera 10.

The actual image file GF can retain the marker segments APP0, APP1, APP2, and APP6 in any combination, but the actual image file must conventionally have marker segments APP1 and APP2 as well as an Exif identifier in order for the image file GF to be handled as a file complying with the Exif file format. When the image file GF is based on the Exif file format, the Exif tag is referred to as the Exif_IFD. The Exif_IFD is pointed to by offset from the TIFF header stored in the 0^{th}_IFD. The image file GF must have the marker segment APP0 in order to be handled as a file complying with the JFIF file format. The image process control data GI can be recorded in the marker segments APP in the same manner as above, and can thus store the image process control data GI properly according to the file structure that is required without modifying the file format on which the image file GF is based.

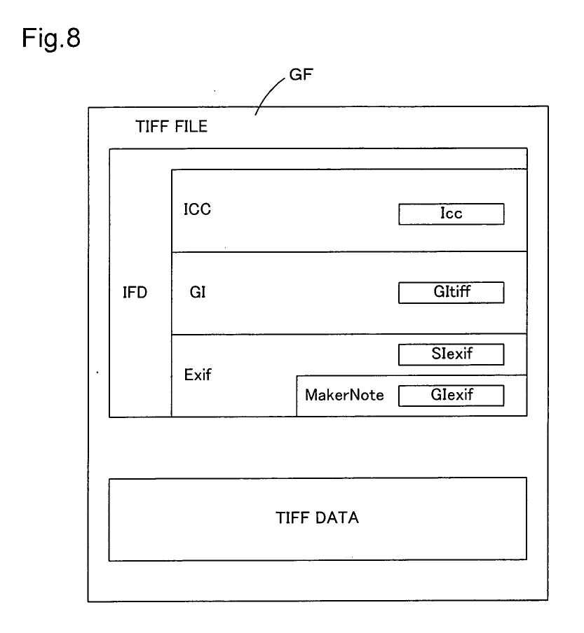

The general structure of the image file according to the TIFF file format which can be used in this example is described with reference to FIG. 8. FIG. 8 schematically illustrates the internal structure of a TIFF file at the IFD level in order to describe the TIFF file format. The terms file structure, data structure, and storage area mean file or data images in a form in which the files or data, etc., are stored in a recording device.

In TIFF files, data related to the image data GD is recorded as tag data. Reversible compression format TIFF data is generally stored, but irreversible compression format JPEG data can also be stored. In TIFF files, data related tot eh image data is stored in IFD (image file directory) units. The example in FIG. 8 includes ICC_IFD in which the ICC profile ICC is recorded, Exif_IFD in which Exif data is recorded, and GI_IFD in which the image process control data GI is recorded. The image process control data GI is recorded as GI tiff data in the GI_IFD and as GI exif data in the Makernote of the Exif_IFD.

Image Output Process in Color Printer 40

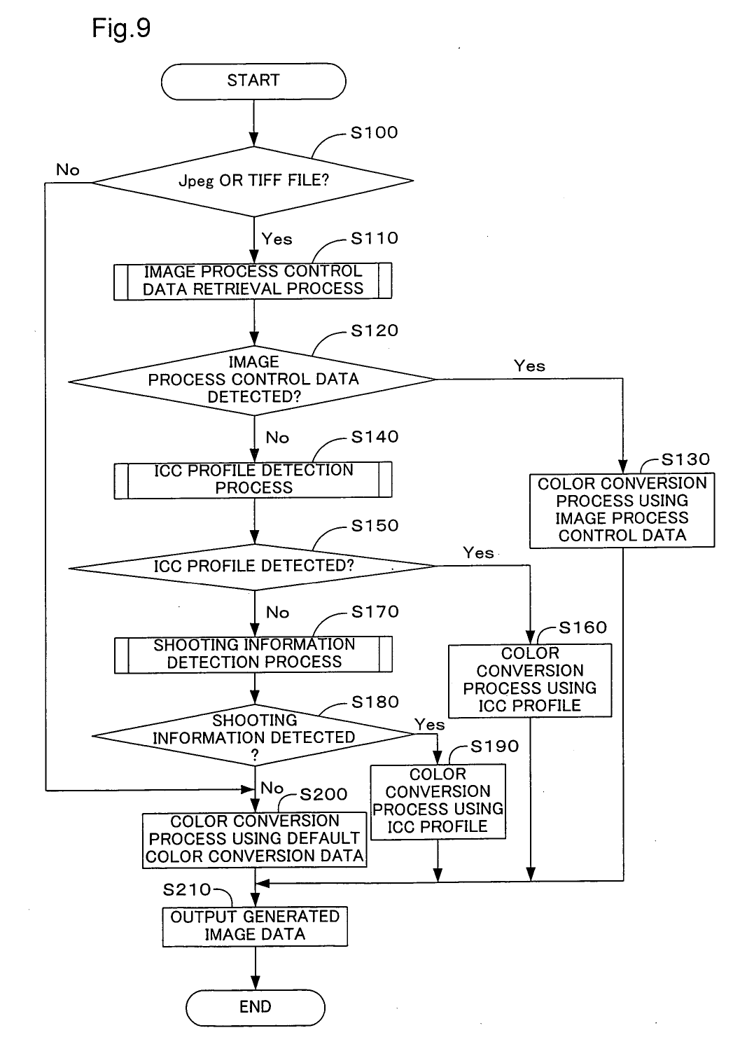

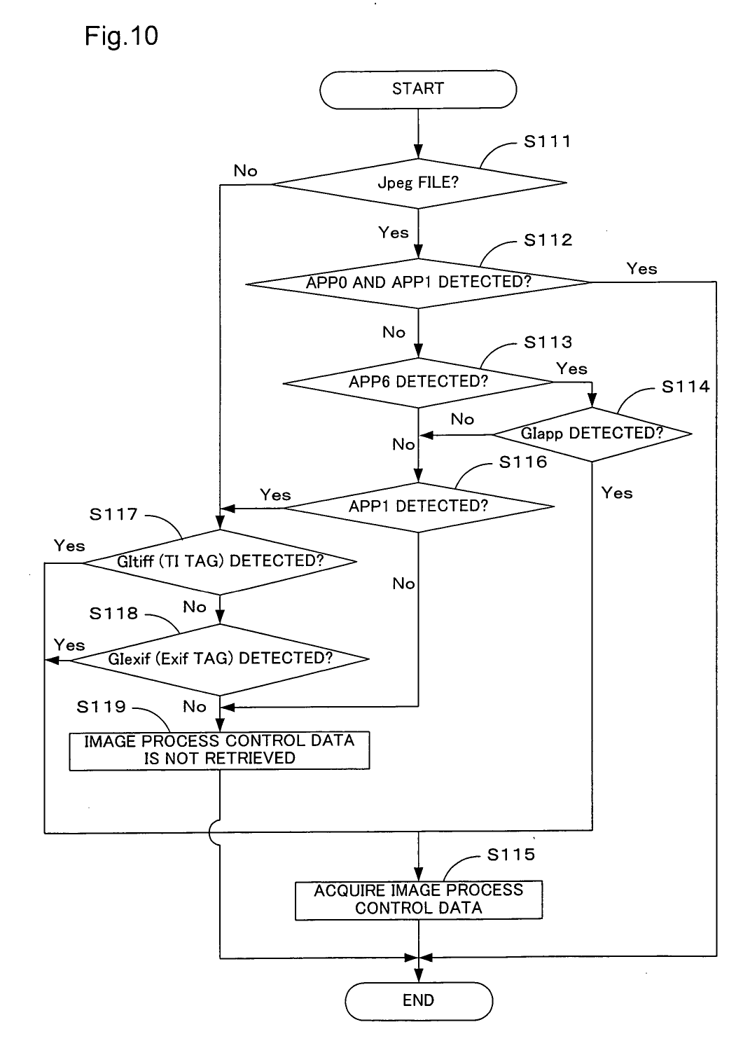

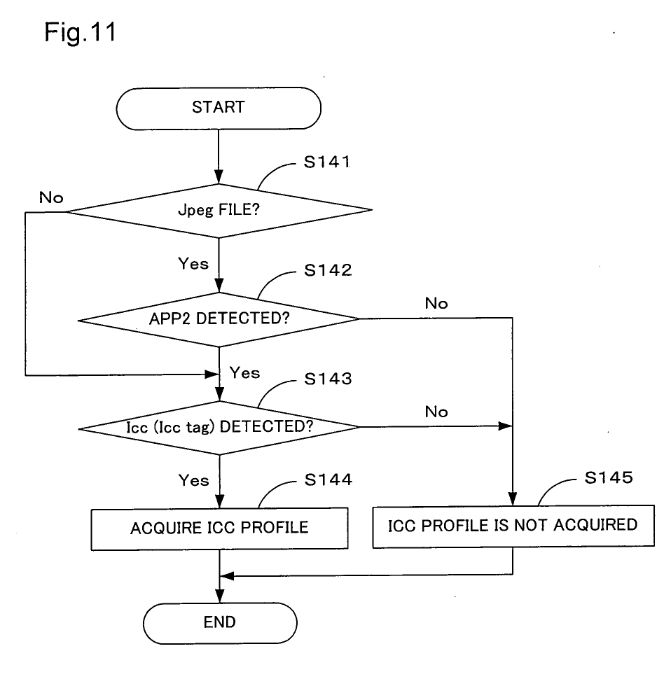

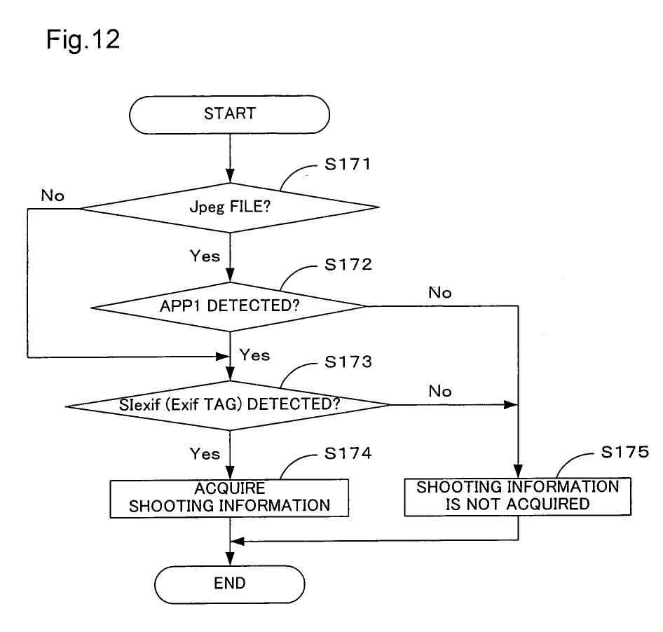

The image process executed by the color printer 40 is described below with reference to FIGS. 9 through 12. FIG. 9 is a flow chart of the routine of the image process including the color conversion process in the image processing device (color printer) of the embodiment. FIG. 10 is a flow chart of a process routine for detecting image process control data. FIG. 11 is a flow chart of a process routine for retrieving ICC profiles. FIG. 12 is a flow chart of a process routine for detecting shooting information.

When the memory card MC is inserted into the slot 44, the control circuit 41 (CPU 411) of the color printer 40 reads the image files GF from the memory card MC and temporarily stores these read image files GF in RAM 412. On the basis of the image file extension, the CPU 411 determines if the read image file GF is a JPEG file storing JPEG data or a TIFF file (Step S100). When the acquired image file GF is determined to be a JPEG file or TIFF file, that is, when the extension is “jpg” or “tif” (Step S100: yes) the CPU 211 runs a process to detect image process control data (Step S110). On the other hand, when the image file GF is determined not to be a JPEG or TIFF file (Step S100: no), the CPU 411 proceeds to Step S200 to run a color conversion process using the default color conversion data, concluding the process routine. The default color conversion data is, for example, data (matrix values for converting the color space of the image data from the sRGB color space to machine-independent color space XYZ color space.

The process for detecting the image process control data is described with reference to FIG. 10. The CPU 411 determines whether or not the image file GF is a JPEG file (Step S111). When the image file GF is determined to be a JPEG file (Step S111: yes), it is determined whether the image file GF includes both an APP marker indicating the marker segment APP0 and an APP marker indicating the marker segment APP1 (Step S112).

When the CPU 411 determines that the image file GF is not a JPEG file (Step S111: no), CPU 411 proceeds to Step 116 because the image file GF is a TIFF file, and determines if the image file GF includes a GI tag. Because, as noted above, the color conversion data is stored in IFD units in TIFF files, the process for detecting the color conversion data can share the detecting process for the marker segment APP1 described below, and will therefore be elaborated in greater detail below.

When the CPU 411 detects both marker segments APP0 and APP1 in the image file GF (Step S112: yes), the process routine is concluded. When both marker segments APP0 and APP1 are detected, it cannot be determined if the image file GF is based on either the JFIF or Exif file formats, and the location of the image process control data GI cannot be properly specified (detected). The process for adjusting picture quality using the image process control data GI is therefore skipped.

The determination process in Step S112 is a process for improving the accuracy for detecting the image process control data GI, and is a step for prioritizing the current de facto standard. It need not necessarily be incorporated in this process routine (it may be omitted from this process routine).

When the CPU 411 does not detect both the marker segments APP0 and APP1 in the image file GF (Step S112: no), CPU 411 determines whether or not the image file GF includes the APP marker indicating marker segment APP6 (Step S113). When the CPU 411 detects the marker segment APP6 in the image file GF (Step S113: yes), CPU 411 determines whether or not the marker segment APP6 includes the image process control data GI app (Step S114). When the CPU 411 detects the image process control data GI app in the marker segment APP6 (Step S14: yes), the CPU 411 acquires the image process control data GI app, completing the process routine.

When the CPU 411 cannot detects the image process control data GI app in the marker segment APP6 (Step S114: no), CPU 411 determines whether or not the image file GF includes the APP marker indicating the marker segment APP1 (Step S116). When the CPU 411 detects the marker segment APP1 in the image file GF (Step S116: yes), CPU 411 determines whether the marker segment APP1 includes the GI tag (Step S117).

When the CPU 411 detects the GI tag in the marker segment APP1 (Step S117: yes), the CPU 411 acquires the image process control data GI tiff (Step S115), completing the process routine. When the CPU 411 does not detect the GI tag in the marker segment APP1 (Step S117: no), CPU 411 determines whether or not the marker segment APP 1 includes the Exif tag (Step S118).

When the CPU 411 detects the Exif tag in the marker segment APP12 (Step S118: yes), the CPU 411 acquires the image process control data GI exif (Step S115), completing the process routine. When the CPU 411 does not detect the Exif tag in the marker segment APP1 (Step S118: no), the process routine is concluded without acquiring the image process control data (Step S119).

The description will now continue with reference to FIG. 9 again. The CPU 411 determines whether or not the image process control data GI app, GI tiff, or GI exif could be detected (Step S120). When any of the image process control data GI app, GI tiff, or GI exif can be detected (Step S120: yes), the color conversion process is run using the color conversion data contained in the image process control data (Step S130), concluding the process routine.

When the processes image file GF stores JPEG image data, the JPEG data is extended (decoded) and the color is converted from YCbCr data to RGB data using a matrix S prior to the color conversion process. As the matrix S is a matrix generally used in the conversion of YCbCr data to RGB data and will be well known to those having ordinary skill in the art, it will not be further elaborated. As it is desirable to linearize the image data GD for color conversion, the image data GD may be linearized by gamma correction using gamma correction values.

The color conversion process can be carried out on the image data, for example, through the application of a matrix having the matrix values noted in the image process control data GI. Specifically, when the image data is RGB data, the first RGB data is color converted to XYZ data using the matrix indicated by the image process control data GI, and the XYZ data is then color converted to second RGB data (such as wRGB) using another matrix (reverse matrix). The color space designated (defined) by the image process control data GI can be considered color space specifying the color space of the image data (image data after the matrix S computation) produced by the digital still camera 10, in which the combination of the digital still camera 10 and color printer 40 has been taken into account.

When the RGB data after the matrix S computation has RGB values outside the color area of the sRGB color system, wRGB color space, for example, in which at least some of the color area is broader than sRGB color space, can be designated as the color space of the RGB data after the matrix S computation to prevent a loss of RGB values, providing a broader wRGB color space at a later stage (working color area).

When the CPU 411 cannot detect any image process control data GI app, GI tiff, or GI exif (Step S120: no), the ICC profile detection process is run (Step S140).

The ICC profile detection process is described with reference to FIG. 11. The CPU 411 determines whether or not the image file GF is a JPEG file (Step S141). When the image file GF is determined to be a JPEG file (Step S141: yes), it is determined whether or not the image file GF includes the APP marker indicating the marker segment APP2 (Step S142).

When the CPU 411 detects the marker segment APP2 (Step S142: yes), CPU 411 determines whether or not the ICC tag is stored in the marker segment APP2 (Step S143).

When the CPU 411 does not detect the marker segment APP2 (Step S142: no), the process routine is concluded without acquiring the ICC profile Icc (Step S145).

When the CPU 411 determines that the image file GF is not a JPEG file (Step S141: no), the image file GF is a TIFF file, and the routine proceeds to Step S143 because the target stored data can be retrieved in IFD units without selecting the appropriate application marker segment.

In Step S143, when the CPU 411 can detect the ICC tag (Step S143: yes), the ICC profile Icc is retrieved (Step S144), and the process routine is concluded.

In Step S143, when the CPU 411 cannot detect the ICC tag (Step S143: no), the process routine is concluded without acquiring the ICC profile Icc (Step S145).

The description will now continue with reference to FIG. 9 again. The CPU 411 determines if the ICC profile Icc could be detected (Step S150). When the ICC profile Icc can be detected (Step S150: yes), the color conversion process is carried out using the ICC profile (Step S160), and the process routine is concluded. The color conversion process can be carried out on the image data, for example, by using a color conversion table or matrix having the matrix values noted in the ICC profile Icc. Specifically, when the image data is RGB data, the first RGB data is color converted to XYZ data using the color conversion table or matrix indicated by the ICC profile Icc, and the XYZ data is then color converted to second RGB data using another matrix (reverse matrix). The color space designated by the ICC profile Icc can be considered color space specifying, by means of machine-independent color space, the color space of the image data produced by the digital still camera 10.

When the CPU 411 cannot detect the ICC profile (Step S150: no), the process for detecting the shooting information SI is carried out (Step S170).

The process for detecting the shooting information is described with reference to FIG. 12. The CPU 411 determines whether or not the image file GF is a JPEG file (Step S171). If it is determined that the image file GF is a JPEG file (Step S171: yes), it is determined whether or not the image file GF includes the AP marker showing the marker segment APP 1 (Step S172).

When the CPU 411 detects the marker segment APP1 (Step S172: yes), it is determined whether or not the Exif tag is stored in the marker segment APP1 (Step S173).

When the CPU 411 cannot detect the marker segment APP1 (Step S172: no), the process routine is concluded without acquiring the shooting information SI (Step S175).

When the CPU 411 determines that the image file GF is not a JPEG file (Step S171: no), the image file GF is a TIFF file, and the process moves to Step S173 because the target stored data can be retrieved in IFD units without selecting the appropriate application marker segment.

In Step S173, when the CPU 411 can detect the Exif tag (Step S173: yes), the shooting information SI is acquireed (Step S174), and the process routine is concluded.

In Step S173, when the CPU 411 cannot detect the Exif tag (Step S173: no), the process routine is concluded without acquiring the shooting information SI (Step S175).

The description will now continue with reference to FIG. 9 again. The CPU 411 determines if the shooting information SI could be detected (Step S180). When the shooting information SI can be detected (Step S180: yes), the color conversion process is carried out using the shooting information SI (Step S190), and the process routine is concluded. The color conversion process can be carried out on the image data, for example, by using the shooting color space noted in the shooting information SI. Specifically, when the color printer 40 has an sRGB-XYZ color conversion matrix or table, and the shooting color space is sRGB data, the sRGB can be converted to XYZ, and the XYZ can then be converted to second RGB. Since the color conversion matrix or color conversion table values are not necessarily specifically noted in the shooting information SI, and the color space data used when the photograph was taken is merely noted, it may not always be possible to carry out the appropriate color conversion if the color printer 40 does not have a color conversion matrix or color conversion table for the color space that has been noted.

When the CPU 411 cannot detect the shooting information SI (Step S180: no), the color conversion process is carried out using the default color conversion data (Step S200), and the routine process is concluded.

After the conclusion of the color conversion, the CPU 411 runs a picture quality adjusting process on the image data in terms of the contrast, sharpness, and color balance parameters. Specifically, the CPU 411 analyzes the image data GD in pixel units to obtain various types of property parameters indicating the properties of the image data GD, such as image statistical data on minimum luminance, maximum luminance, and representative brightness. The CPU 411 determines the extent of correction for eliminating or reducing the difference between predetermined standard values for the various property parameters stored in ROM 413 and the image statistical values obtained by the above analysis, and corrects the RGB values of the image data GD. The image data GD may be corrected, for example, by applying the determined correction values to a tone curve specifying the relationship of output values to input values, and by applying the image data GD as input values to the tone curve. When the image process control data GI can be acquired, the image process control data GI can be used to modify the extent to which the difference is eliminated or reduced (corrected) between the standard values and image statistical values. It is thus possible to carry out a picture quality adjusting process in accordance with the intention of the photographer.

The CPU 411 runs a color conversion process to convert the image data (RGB data) which has undergone the picture quality adjusting process to CMYK data. That is, the color system of the image data is converted to the CMYK color system which is the system used when the color printer 40 executes the printing process. Specifically, the process is carried out using a look up table matching the RGB color system and the CMYK color system, which is stored in ROM 413.

The CPU 411 finally carries out the printing output process using the resulting image data. In the printing output (image output) process, the CPU 411 converts the RGB to CMYK using a look up table or the like, runs a half tone process, and runs a resolution conversion process, sending the processed data in the form of output image data (raster data) including a print command to the printing image output component 43. The printing image output component 43 drives printing heads according to the print command included in the raster data, forming an image based on the output image data on print media such as paper media. The output print data need not necessarily include a print command. It need hardly be mentioned that the print command may be issued separately from the output image data to the printing image output component 43.

As noted above, in the color printer 40 (image processing device) in this example, image process control data GI, ICC profile Icc, and shooting information SI are retrieved as color conversion data from the image file GF, and a color conversion process is carried out on the image data GD using the color conversion data that can obtained. Nowadays, it is highly possible that one of these three types of color conversion data will be associated with the image data GD, making it possible to carry out a color conversion process suitable for various types of image data GD by using any of these types of color conversion data. It will thus be possible to improve the picture quality of the output image.

As the color conversion data is retrieved in the order image process control data GI, ICC profile Icc, and shooting information SI, a color conversion that is even more suitable for the image data GD can be carried out. As noted previously, the image process control data GI has color conversion data adapted to the combination of the image data generating device and the image output device, resulting in color conversion results reflecting the color reproducing properties of the image data generating device and image output device. Because the ICC profile Icc allows the color space of at least the image data generating device to be converted to machine-independent color space, the color conversion process can be carried out without a loss of the color design of the image data generating device. Because, furthermore, the color space at the time the photograph was taken is noted in the shooting information SI, the color printer 40 serving as the image processing device can carry out the color conversion process based on the knowledge of the color space defining the input image data GD.

The image file GF used in this example was composed in such a way as to comprise a shared file structure after the TIFF header, that is, the IFD, making it possible to share the retrieval process after the TIFF header by the color printer 40.

The image file GF used in this example has identifiers and tag codes over various levels in order to prevent misidentification of the image process control data GI. In the color printer in this example, the image process control data GI is specified upon the retrieval of the identifier and tag code, allowing the appropriate picture quality adjusting process to be carried out without misidentifying the image process control data GI.

### OTHER EXAMPLES

In the above example, the color printer 40 handled the color conversion data in both matrix and table form, but when the color printer 40 runs the color conversion process on the image data by computing a 3×3 matrix, the ICC profile Icc may be used only when the ICC profile stores matrix values for a 3×3 matrix. For example, when the image process control data GI stores the color conversion data in the form of matrix values, and the color printer 40 has the function of interpreting the image process control data GI, ICC profiles Icc having a function interpretable format are selected.

In the above example, image files GF in JFIF, Exif, and TIFF file formats were given as specific examples of image files GF, but other image file formats are also possible in the invention. That is, the image files should include image data GD and image process control data GI associated with at least the image data GD.

In the above example, the image process control data GI was retrieved in the order APP6, TIFF (GI tag), and Makernote (Exif tag) for efficient retrieval, but other orders of retrieval may also be used. The order of retrieval does not affect the nature of the image process. Other orders of retrieval will not result in changes in terms of the ability to output properly processed images.

In the above example, the image process control data GI is retrieved first, but the ICC profile Icc or shooting information SI may also be retrieved first. It is possible to carry out a color conversion process on image data using at least the usable color conversion data by retrieving and acquiring other usable color conversion data without being limited to specific color conversion data associated with the image data.

In the above example, a color printer 40 was used as the image processing device, but a display device 20 or personal computer 30 may also be used. In such cases, the same effects as above can be obtained. In those cases, an image processing program (display driver) for implementing the image process described with reference to FIGS. 9 through 12, for example, may be carried out by the display device as the output device or the personal computer 30. Alternatively, when a CRT functions as a computer display device, the image process program may be carried out on the computer side. The image data that is ultimately output will have RGB color space, not CMYK color space.

In the above example, the image process was carried out by software, that is, in the form of a computer program, but it may also be done using image processing hardware circuitry comprising a logical circuit for implementing the above processes (steps). In such cases, the load on the CPU 411 can be alleviated, and the process can be carried out more rapidly. Image processing hardware circuits can be mounted in the form of mounted circuits on the display 20 or color printer 40, for example, or in the form of add-on cards to the personal computer 30.

In the example above, the color printer 40 was used as the output device, but display devices such as CRT, LCD, and projectors can also be used. In such cases, the picture quality of the image displayed on display devices such as CRT can be improved in the same manner as when done using the color printer 40.

The digital still camera 10 and color printer 40 used in the above example are ultimately only examples, and their structure is not limited to the details of the examples. The digital still camera 10 should comprise at least the function of being able to generate the image data GD in the above example or image data GD with associated color conversion data. The color printer 40 should at least be able to execute a color conversion process on the image data GD by retrieving color conversion data from image data GD with associated color conversion data or image files GF capable of storing image process control data GI, ICC profiles, and shooting information SI as color conversion data, and using the retrieved color conversion data to run a color conversion process on the image data GD.

In the above example, the examples of image data GD and color conversion data contained in the same image file GF, but the image data GD and color conversion data need not necessarily be stored in the same file. That is, the image data GD and color conversion data should be associated. For example, associated data associating the image data GD and color conversion data may be generated, one or more sets of image data GD and color conversion data may be stored in individual files, and the image data GD mayor be processed with reference to the associated color conversion data when processed. Motion picture files stored on optical disk media such as CD-ROM, CD-R, DVD-ROM, and DVD-RAM may also be included in image files GF.

The image processing device and method of the invention were described on the basis of the examples above, but embodiments for working the inventions described above were for the purpose of facilitating an understanding of the invention, and do not limit the invention. The invention can be modified without departing from the spirit and scope of the invention, and equivalent products are, of course, included in the invention.

The following Japanese patent application as the basis of the priority claim of this application are incorporated in the disclosure hereof by reference: Japanese Patent Application No. 2004-57733 (filing date: Mar. 2, 2004).

1. An image processing device for implementing a color conversion process on image data associated with at least one of first through third color conversion data, the image processing device comprising:
image data acquisition module that acquires the image data;
color conversion data retrieval module that retrieves the first through third color conversion data associated with the acquired image data; and
color conversion processing module that executes the color conversion process on the image data according to the first color conversion data when the first color conversion data is retrieved.

2. An image processing device according to claim 1, wherein
the color conversion processing module executes the color conversion process on the image data according to the second color conversion data when the first color conversion data is not retrieved but the second color conversion data is retrieved.

3. An image processing device according to claim 2, wherein
the color conversion processing module executes the color conversion process on the image data according to the third color conversion data when the second color conversion data is not retrieved but the third color conversion data is retrieved.

4. An image processing device according to claim 3 further comprising
storage module that storing default color conversion data,
wherein the color conversion processing module executes the color conversion process on the image data according to the default color conversion data when the third color conversion data is not retrieved.

5. An image processing device according to claim 1, wherein
the first color conversion data is image process control data defining the image processing conditions for associated image data, the second color conversion data is ICC profiles, and the third color conversion data is shooting information indicating the conditions at the time of shooting.

6. An image processing device according to claim 1 further comprising:
output image data generating module that generates output image data using the image data that is color converted; and
image output module that outputs an image using generated output image data.

7. An image processing device for executing a color conversion process on image data using image files that store at least any one of image data, image process control data that defines the image processing conditions for the image data and is stored in a plurality of storage locations in one recording format, ICC profiles in which the storage location in one recording format is defined, and shooting information indicating the conditions at the time the shooting, in which the storage location in one recording format is defined, said image processing device comprising:
image file acquiring module that acquires the image files;
format determination module that determines the recording format of the acquired image file;
image process control data retrieval module that retrieves image process control data at the plurality of storage locations according to the determined recording format; and
color conversion processing module that executing the color conversion process on the image data according to the retrieved image process control data when the image process control data is retrieved.

8. An image processing device according to claim 7 further comprising
ICC profile retrieval module that retrieves ICC profiles at the defined storage location when the image process control data is not retrieved at the plurality of storage locations, wherein
the color conversion processing module that executes the color conversion process on the image data according to the ICC profile when the ICC profile is retrieved.

9. An image processing device according to claim 8 further comprising
shooting information retrieval module that retrieves the shooting information at the defined storage location when the ICC profile is not retrieved at the defined storage location, wherein
the color conversion processing module executes the color conversion process on the image data according to the shooting information when the shooting information is retrieved.

10. An image processing device according to claim 7, wherein
the image file is a JPEG data storage file having at least any one of a first application marker segment in which the image process control data is storable, a second application marker segment in which the ICC profile is storable, and a third application marker segment in which at least one of the image process control data or shooting information is storable at the same hierarchy, and
the image process control data retrieval module retrieves the image process control data in the order of the storage location of the third application marker segment and the storage location of the first application marker segment.

11. An image processing device according to claim 7, wherein
the image file is a JPEG data storage file having at least any one of a first application marker segment in which the image process control data is storable, a second application marker segment in which the ICC profile is storable, and a third application marker segment in which at least one of the image process control data or shooting information is storable at the same hierarchy, and
the image process control data retrieval module retrieves the image process control data in the order of the storage location of the first application marker segment and the storage location of the third application marker segment.

12. An image processing device according to claim 10 further comprising:
shooting information retrieval module that retries the shooting information from the third application marker segment, wherein
the third application marker segment is capable of storing the image process control data at a subordinate hierarchy of the shooting information, and
the image process control data retrieval module retrieves the image process control data at a subordinate hierarchy of the shooting information of the third application marker segment when image process control data is not retrieved at the storage locations of the first and third application marker segments but the shooting information is retrieved by the shooting information retrieval module.

13. An image processing device according to claim 12 further comprising
ICC profile retrieval module that retrieves the ICC profile from the second application marker segment, wherein
the color conversion processing module executes the color conversion process on the image data using the retrieved ICC profile when the image process control data is not retrieved by the image process control data retrieval module but the ICC profile is retrieved by the ICC profile retrieval module.

14. An image processing device according to claim 13, wherein
the color conversion processing module executes a color conversion process on the image data using the shooting information when the ICC profile is not retrieved from the second application marker segment but the shooting information is retrieved from the third application marker segment.

15. An image processing device according to claim 7, wherein
the image file is a TIFF file having at least any one of a first in image file directory in which the image process control data is storable, a second image file directory in which the ICC profile is storable, and a third image file directory in which the shooting information is storable, and
the image process control data retrieval module retrieves the image process control data in the order of the storage location of the first image file directory and the third image file directory.

16. An image processing device according to claim 15 further comprising
shooting information retrieval module that retrieves the shooting information from the third image file directory, wherein
the third image file directory is capable of storing the image process control data at a subordinate hierarchy of the shooting information, and
the image process control data retrieval module retrieves the image process control data at a subordinate hierarchy of the shooting information of the third image file directory when image process control data is not retrieved at the first image file directory but the shooting information is retrieved by the shooting information retrieval module.

17. An image processing device according to claim 16 further comprising
ICC profile retrieval module that retrieves the ICC profile from the second image file directory, wherein
the color conversion processing module executes the color conversion process on the image data using the ICC profile that has been retrieved when the image process control data is not retrieved by the image process control data retrieval module but the ICC profile is retrieved by the ICC profile retrieval module.

18. An image processing device according to claim 17, wherein
the color conversion processing module executes a color conversion process on the image data using the shooting information when the ICC profile is not retrieved from the second image file directory but the shooting information is retrieved from the third image file directory.

19. An image processing method of implementing a color conversion process on image data that is associated with at least one of first through third color conversion data, the image processing method comprising:
acquiring the image data;
retrieving the first through third color conversion data associated with the acquired image data; and
executing the color conversion process on the image data according to the first color conversion data when the first color conversion data is retrieved.

20. An image processing method of executing a color conversion process on image data using image files that store at least any one of image data, image process control data that defines the image processing conditions for the image data and is storable in a plurality of storage locations in a recording format, ICC profiles in which the storage location in a recording format is defined, and shooting information indicating the conditions at the time of the shooting, in which the storage location in a recording format is defined, said image processing method comprising:
acquiring the image files;
determining the recording format of the acquired image file;
retrieving image process control data at the plurality of storage locations according to the determined recording format; and
executing the color conversion process on the image data according to the retrieved image process control data when the image process control data is retrieved.
